(19) United States
(12) Patent Application Publication
(10) Pub. No.: US 2019/0385826 A1
(43) Pub. Date: Dec. 19, 2019

(54) PLASMA PROCESSING DEVICE

(71) Applicant: Industrial Technology Research Institute, Hsin-Chu (TW)

(72) Inventors: CHIH-CHIANG WENG, Taoyuan City (TW); CHEN-DER TSAI, Hsinchu County (TW); CHIA-JEN TING, Hsinchu County (TW); JUI-MEI HSU, Hsinchu County (TW); YO-SUNG LEE, New Taipei City (TW); CHIH-HUNG LIU, Taichung City (TW)

(21) Appl. No.: 16/180,266

(22) Filed: Nov. 5, 2018

Related U.S. Application Data
(60) Provisional application No. 62/684,226, filed on Jun. 13, 2018.

(30) Foreign Application Priority Data
Aug. 31, 2018 (TW) 107130458

(51) Int. Cl. H01J 37/32; H01L 21/306

(52) U.S. Cl. CPC H01J 37/32568; H01L 21/30625; H01J 37/32541; H01J 37/32559; H01L 29/1608; H01J 37/32449; H01J 37/32733; H01J 37/32825; H01J 37/32844

(57) ABSTRACT

A plasma processing device includes an upper electrode assembly and a lower electrode assembly. The upper electrode assembly has a plurality of post electrodes, made of a conductive material, protruding individually out of one surface of the upper electrode assembly, and connected to a plasma source. A plasma deficiency area having no post electrode is disposed in a center portion of the upper electrode assembly. The plurality of post electrodes are disposed in a ringlike electrode distribution area surrounding concentrically the plasma deficiency area. The lower electrode assembly is rotatable, made of a conducting material, and covered by a dielectric material.

### CROSS REFERENCE TO RELATED APPLICATION

This application claims the benefits of the filing date of U.S. Provisional Patent Application Ser. No. 62/684,226, filed on Jun. 13, 2018, and also claims priority to Taiwan Patent Application No. 107130458 filed in the Taiwan Patent Office on Aug. 31, 2018. The contents of this prior applications are hereby incorporated by reference in their entirety.

### TECHNICAL FIELD

The present disclosure relates in general to a plasma processing device, and more particularly to a high-efficiency large-area planar atmospheric-pressure plasma processing device that can process plural workpieces simultaneously with enhanced plasma uniformity and an improved material-removing rate of a polishing process.

### BACKGROUND

In the art, developments in silicon-based power components are hindered by material properties, and thus hard to meet demands in high frequencies, high temperatures, high power, high performance, ability against harsh environments and portability. The silicon carbide (SiC), one of wide band-gap semiconductor materials, is featured by high-voltage endurance, high saturated electron drift velocities, high thermal conductivity and so on, and thus is suitable for producing high-power and high-temperature semiconductor elements. Recently, the third-generation semiconductor materials, represented usually by SiC, are widely applied to various fields including optoelectronic devices and power electronic devices. With superior semiconductor properties, the third-generation semiconductor materials would contribute definitely to innovative developments in various industrial manifolds, and to provide a bright future in applications and market potential.

Nevertheless, though SiC chip may be excellent in material properties, yet it responds ill in hardness and brittleness (with 9.25˜9.5 Mohs hardness, which is second to the diamond). Hence, while in a final polishing process for removing a 1˜2 μm depth material, for example, a process time of hours or even more than ten hours is usually required if a conventional chemical mechanical polishing (CMP) process is applied. Obviously, a necking manufacturing step is thus formed for producing wafers, and the cost for the entire manufacturing process would go high as well. Thereupon, people in the upstream industry of wafer manufacturing are all devoted to uplift the material-removing rate of the polishing process for the large-scale SiC chips (diameter ≥4 inches).

In particular, for a planar atmospheric-pressure plasma, a major concern is that, as planar electrodes are introduced, the generation of the atmospheric-pressure plasma would be highly affected by the parallelism of these planar electrodes. In the case that a non-uniform arrangement for the planar electrodes is applied, discrete concentrated atmospheric-pressure plasma would occur naturally to those locations having denser distributions of the planar electrodes, even under the same parameters, according to Paschen's curves. Under this circumstance, it is hard to control patterns of the plasma. Thus, while in producing a large-area planar atmospheric-pressure plasma, the arrangement control at parallelism between two planar electrodes is extremely critical.

Accordingly, an improved large-area planar atmospheric-pressure plasma processing device that can process plural workpieces simultaneously with enhanced plasma uniformity and a satisfied material-removing rate of a polishing process is urgently needed and welcome definitely to the skill in the art.

### SUMMARY

In this disclosure, an embodiment of the plasma processing device includes an upper electrode assembly and a lower electrode assembly.

The upper electrode assembly includes a plurality of post electrodes protruding toward the lower electrode assembly from a reaction surface of the upper electrode assembly. The plurality of post electrodes are individually connected with a plasma power source. A plasma deficiency area is defined in a central area of the upper electrode assembly where none of the post electrodes is located, and an annular electrode distribution area is defined between a boundary of the plasma deficiency area and a smallest circumference encircling all the plurality of post electrodes. An upper plasma-generating region is formed under the plurality of post electrodes with respect to the annular electrode distribution area.

The lower electrode assembly, located under and separated from the upper electrode assembly, has at least one built-in type electrode covered by a dielectric material, and is grounded and rotatable. Between the upper electrode assembly and the lower electrode assembly, a plasma-reaction zone including the plasma-generating region is formed.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic exploded view of an embodiment of the plasma processing device in accordance with the present disclosure;

FIG. 2 is a schematic view showing an embodiment of an arrangement of the post electrodes in accordance with the present disclosure;

FIG. 3 is a schematic cross-sectional view of FIG. 1 along line A-A;

FIG. 4 is a schematic view showing an embodiment of an arrangement of the cooling channel in accordance with the present disclosure;

FIG. 5 is a schematic view showing an embodiment of an arrangement of the vent holes with respect to the plurality of post electrodes in accordance with the present disclosure;

FIG. 6 is a schematic top view of an embodiment of the reaction shield in accordance with the present disclosure, also showing relative positions of the upper electrode assembly and the lower electrode assembly in dashed lines;

FIG. 7 is a schematic cross-sectional view of FIG. 6 along line B-B, with the reaction shield located at the process position;

FIG. 8 is a schematic cross-sectional view of FIG. 6 along line B-B, with the reaction shield located at the material-loading/unloading position;

FIG. 9 is a schematic exploded view of an embodiment of the lower electrode assembly in accordance with the present disclosure; and

FIG. 10 is a schematic exploded view of another embodiment of the lower electrode assembly in accordance with the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

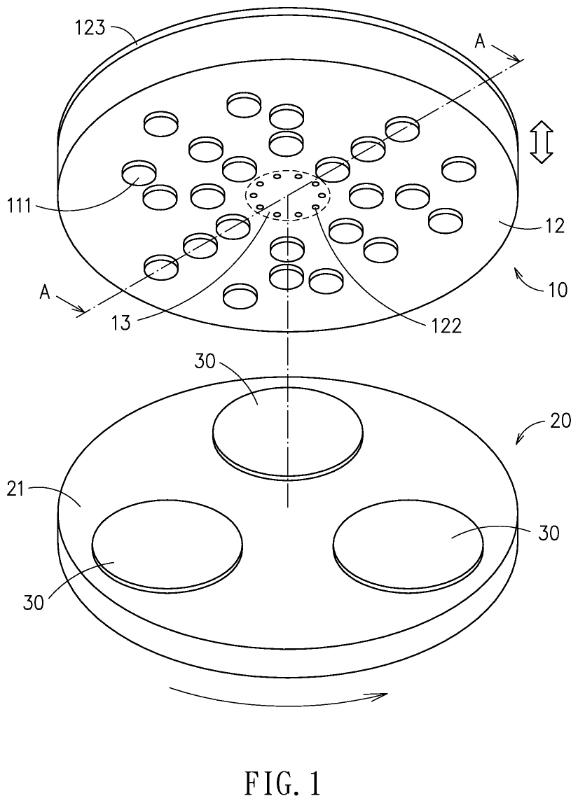

Referring now to FIG. 1, an embodiment of the plasma processing device in accordance with the present disclosure is schematically shown. In this embodiment, the plasma processing device includes an upper electrode assembly 10 and a lower electrode assembly 20, in which the lower electrode assembly 20 is grounded and rotationally driven, while the upper electrode assembly 10 is vertically movable with respect to the lower electrode assembly 20. The upper electrode assembly 10 is used at least for providing a plasma source and a process gas. The lower electrode assembly 20 is used as a carrier platform of workpieces 30, and also as a ground electrode for the plasma power source. A space between the upper electrode assembly 10 and the lower electrode assembly 20 is defined as a plasma-reaction zone. The lower electrode assembly 20 can serve independently as a ground electrode for a large-area auxiliary plasma processing apparatus, or as a ceramic wafer carrier shared with a chemical mechanical polishing apparatus.

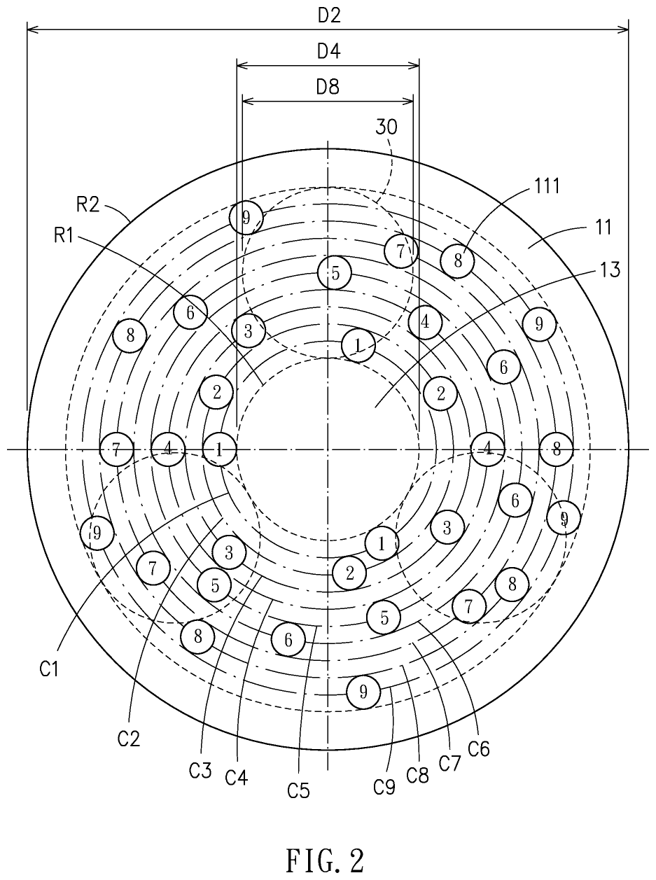

Referring to FIG. 1 and FIG. 2, one side of the upper electrode assembly 10 (a bottom side of the upper electrode assembly 10 shown in the figure) is furnished with a plurality of post electrodes 111, and a plasma deficiency area 13 without any post electrode 111 is set to a central area of the bottom side of the upper electrode assembly 10. Since no post electrode 111 exists within the plasma deficiency area 13, thus the plasma deficiency area 13 can be used to construct blind plates or ventilation holes. As shown, the plurality of post electrodes 111 are disposed within an annular band (or ringlike) area between a boundary R1 of the plasma deficiency area 13 and an outer rim R2 of the upper electrode assembly 10. With the post electrodes 111, an annular electrode distribution area is formed accordingly in the annular band area. Also, a plasma-generating region (defined correspondingly with the annular electrode distribution area) is formed under the annular band area between the boundary R1 of the plasma deficiency area 13 and the outer rim R2 of the upper electrode assembly 10. Practically, both the annular electrode distribution area and the plasma-generating region are related spatially to loading positions of the workpieces 30 to be processed on the lower electrode assembly 20. As shown in the figure, the workpieces 30 are all disk-shaped, and thus a radial width of the annular electrode distribution area or the plasma-generating region is at least equal to a diameter of the largest workpiece 30.

Referring to FIG. 2, one of many arrangements for the post electrodes 111 is present simply for an explanation purpose. In this disclosure, the post electrode 111 is formed by a conductive material coated, covered or wrapped by a dielectric material. As shown, the post electrodes 111 surrounding a center are discretely distributed to a plurality of concentric circles (C1˜C9). In each of the circles C1˜C9, at least one post electrode 111 is located. In this embodiment shown in FIG. 2, each of the first to fifth circles C1˜C5 has 3 post electrodes 111, each of the sixth and seventh circles C6˜C7 has 4 post electrodes 111, and each of the eighth and ninth circles C8˜C9 has 5 post electrodes 111. A digit (1˜9) to denote the instant circle number (C1˜C9) is filled to top each post electrode 111 in FIG. 2. Namely, the post electrodes 111 located at the same concentric circle would be assigned with the same digit. It is noted that, in this arrangement, a quantity of post electrodes 111 in the outer circle is greater than or equal to (i.e., no less than) that in the inner circle. In addition, each of the circles (C1˜C9) would be accompanied by a trace ring (not shown in the figure) generated by revolving the post electrodes 111 in the same concentric circle about the aforesaid center. The neighboring trace rings (i.e., the two trace rings corresponding to the two neighboring concentric circles) are at least contacted (i.e., partly overlapped or at least tangential to each other). The post electrodes 111 at the same concentric circle may have different diameters. A radial width of the trace ring is the same as a diameter of the largest post electrode 111 at the corresponding concentric circle. By integrating all the trace rings corresponding to the circles C1˜C9, the annular electrode distribution area is formed.

To estimate a quantity of the post electrodes at each individual concentric circle, the following criteria can be applied.

(Diameter of the circle×Circular constant Pi)/Reference arc length

The estimated quantity (an integer) of the post electrodes at each individual circle is then obtained by rounding the corresponding calculated number of the post electrodes.

In the foregoing calculation, the reference arc length can be determined by the following equation.

(Average circumferential arc length shared by each single post electrode at the same concentric circle−Reference arc length)/Reference arc length×100%

Then, the chosen reference arc length is the one that contributes the least difference in every circumferential length. For example, as the reference arc length is set to be 80 or 100, the maximum circumferential rounding percentages is −9.2% (with a total quantity of 112 or 91, respectively).

While in a consideration of a broader processing area, the quantity of the post electrodes at the outer circle would be increased as well. Under this circumstance, the resulted quantity of the post electrodes determined according to the aforesaid manipulation in judging the circumferential rounding percentages might be too big, and thus a resort to accept a larger maximal circumferential rounding percentage may be applied. For example, as the reference arc length is 110, the maximal circumferential rounding percentage is about 10%, and the total quantity of post electrodes is 82.

When the references length is different, the total quantity of post electrodes is also different as follows.

In the case of Reference arc length=70:

| | | | | | | | Average circum- | Circum- |
|---|---|---|---|---|---|---|---|---|
| | | | | | | | ferential arc length | ferential |
| | | | | | | | shared by each | rounding |
| Circle | | | Circum- | Ref. arc | Calculated | Estimated | single post | percentage |
| # | Dia. | Pi | ference | length | number | quantity | electrode | (%) |
| 1 | 99.6 | 3.14159 | 312.9024 | 70 | 4.470034 | 4 | 78.225591 | 11.75084 |
| 2 | 115.6 | 3.14159 | 363.1678 | 70 | 5.188111 | 5 | 72.6335608 | 3.76223 |
| 3 | 131.6 | 3.14159 | 413.4332 | 70 | 5.906189 | 6 | 68.90554067 | −1.56351 |
| 4 | 147.6 | 3.14159 | 463.6987 | 70 | 6.624267 | 7 | 66.24266914 | −5.36762 |
| 5 | 163.6 | 3.14159 | 513.9641 | 70 | 7.342345 | 7 | 73.42344629 | 4.890638 |
| 6 | 179.6 | 3.14159 | 564.2296 | 70 | 8.060422 | 8 | 70.5286955 | 0.755279 |
| 7 | 195.6 | 3.14159 | 614.495 | 70 | 8.7785 | 9 | 68.27722267 | −2.46111 |
| 8 | 211.6 | 3.14159 | 664.7604 | 70 | 9.496578 | 9 | 73.86227156 | 5.517531 |
| 9 | 227.6 | 3.14159 | 715.0259 | 70 | 10.21466 | 10 | 71.5025884 | 2.146555 |
| 10 | 243.6 | 3.14159 | 765.2913 | 70 | 10.93273 | 11 | 69.57193855 | −0.61152 |
| 11 | 259.6 | 3.14159 | 815.5568 | 70 | 11.65081 | 12 | 67.96306367 | −2.90991 |
| 12 | 275.6 | 3.14159 | 865.8222 | 70 | 12.36889 | 12 | 72.15185033 | 3.074072 |
| 13 | 291.6 | 3.14159 | 916.0876 | 70 | 13.08697 | 13 | 70.46828031 | 0.668972 |
| 14 | 307.6 | 3.14159 | 966.3531 | 70 | 13.80504 | 14 | 69.02522029 | −1.39254 |
| | | | | | Total | 127 | | |
| | | | | | quantity | | | |

In the case of Reference arc length=100:

| | | | | | | | Average circum- | Circum- |
|---|---|---|---|---|---|---|---|---|
| | | | | | | | ferential arc length | ferential |
| | | | | | | | shared by each | rounding |
| Circle | | | Circum- | Ref. arc | Calculated | Estimated | single post | percentage |
| # | Dia. | Pi | ference | length | number | quantity | electrode | (%) |
| 1 | 99.6 | 3.14159 | 312.9024 | 100 | 3.129024 | 3 | 104.300788 | 4.300788 |
| 2 | 115.6 | 3.14159 | 363.1678 | 100 | 3.631678 | 4 | 90.791951 | −9.20805 |
| 3 | 131.6 | 3.14159 | 413.4332 | 100 | 4.134332 | 4 | 103.358311 | 3.358311 |
| 4 | 147.6 | 3.14159 | 463.6987 | 100 | 4.636987 | 5 | 92.7397368 | −7.26026 |
| 5 | 163.6 | 3.14159 | 513.9641 | 100 | 5.139641 | 5 | 102.7928248 | 2.792825 |
| 6 | 179.6 | 3.14159 | 564.2296 | 100 | 5.642296 | 6 | 94.03826067 | −5.96174 |
| 7 | 195.6 | 3.14159 | 614.495 | 100 | 6.14495 | 6 | 102.415834 | 2.415834 |
| 8 | 211.6 | 3.14159 | 664.7604 | 100 | 6.647604 | 7 | 94.96577771 | −5.03422 |
| 9 | 227.6 | 3.14159 | 715.0259 | 100 | 7.150259 | 7 | 102.1465549 | 2.146555 |
| 10 | 243.6 | 3.14159 | 765.2913 | 100 | 7.652913 | 8 | 95.6614155 | −4.33858 |
| 11 | 259.6 | 3.14159 | 815.5568 | 100 | 8.155568 | 8 | 101.9445955 | 1.944596 |
| 12 | 275.6 | 3.14159 | 865.8222 | 100 | 8.658222 | 9 | 96.20246711 | −3.79753 |
| 13 | 291.6 | 3.14159 | 916.0876 | 100 | 9.160876 | 9 | 101.787516 | 1.787516 |
| 14 | 307.6 | 3.14159 | 966.3531 | 100 | 9.663531 | 10 | 96.6353084 | −3.36469 |
| | | | | | Total | 91 | | |
| | | | | | quantity | | | |

In the case of Reference arc length=130:

| | | | | | | | Average circum- | Circum- |
|---|---|---|---|---|---|---|---|---|
| | | | | | | | ferential arc length | ferential |
| | | | | | | | shared by each | rounding |
| Circle | | | Circum- | Ref. arc | Calculated | Estimated | single post | percentage |
| # | Dia. | Pi | ference | length | number | quantity | electrode | (%) |
| 1 | 99.6 | 3.14159 | 312.9024 | 130 | 2.406941 | 2 | 156.451182 | 20.34706 |
| 2 | 115.6 | 3.14159 | 363.1678 | 130 | 2.793598 | 3 | 121.0559347 | −6.88005 |
| 3 | 131.6 | 3.14159 | 413.4332 | 130 | 3.180256 | 3 | 137.8110813 | 6.008524 |
| 4 | 147.6 | 3.14159 | 463.6987 | 130 | 3.566913 | 4 | 115.924671 | −10.8272 |
| 5 | 163.6 | 3.14159 | 513.9641 | 130 | 3.95357 | 4 | 128.491031 | −1.16075 |
| 6 | 179.6 | 3.14159 | 564.2296 | 130 | 4.340227 | 4 | 141.057391 | 8.505685 |
| 7 | 195.6 | 3.14159 | 614.495 | 130 | 4.726885 | 5 | 122.8990008 | −5.46231 |
| 8 | 211.6 | 3.14159 | 664.7604 | 130 | 5.113542 | 5 | 132.9520888 | 2.270838 |
| 9 | 227.6 | 3.14159 | 715.0259 | 130 | 5.500199 | 6 | 119.1709807 | −8.33001 |
| 10 | 243.6 | 3.14159 | 765.2913 | 130 | 5.886856 | 6 | 127.548554 | −1.88573 |
| 11 | 259.6 | 3.14159 | 815.5568 | 130 | 6.273514 | 6 | 135.9261273 | 4.558559 |
| 12 | 275.6 | 3.14159 | 865.8222 | 130 | 6.660171 | 7 | 123.6888863 | −4.8547 |
| 13 | 291.6 | 3.14159 | 916.0876 | 130 | 7.046828 | 7 | 130.8696634 | 0.668972 |
| 14 | 307.6 | 3.14159 | 966.3531 | 130 | 7.433485 | 7 | 138.0504406 | 6.192647 |
| | | | | | Total | 69 | | |
| | | | | | quantity | | | |

In addition, regarding the position arrangement of the post electrodes, based on the estimated quantity of the post electrodes for each individual circle, the excel random function rand( )×360 can be applied to randomly determine an angular position (unit degree is omitted in the following description) for locating the first post electrode of each circle, and then the 2nd˜n-th post electrodes can be evenly distributed along the circle. For example, in the case that the first circle has three post electrodes, and thus reasonable angular spacing would be 360/3=120; in the case that the third circle has four post electrodes, then the reasonable angular spacing would be 360/4=90; and, so forth. If a calculated angle exceeds 360, then a modification thereupon by subtracting 360 is required. By having circle 1 in the following table as a typical example, it is obvious that three post electrodes should be included along circle 1. If a random number 276 is picked for planting the first post electrode, then the second post electrode would be located at an angular position 276+(360/3)=396. Since 396 exceeds 360, then, according to the aforesaid criterion, the angular position to plant the second post electrode would be adjusted to be 396−360=36. Similarly, the third post electrode would be at 276+2×(360/3)=516, and adjusted to be 516−360=156. Namely, three angular positions to locate these three post electrodes along circle 1 are 276, 36, and 156. In addition, while in picking up a random number, if spacing between two neighboring circles is smaller than a diameter of the post electrode, then re-picking another random number is necessary. If overlapping happens to nearby post electrodes, then the entire circle may be adjusted by angular shifting, or at least one involved post electrode should be re-located. The post electrodes need to be evenly distributed all over the arrangement plane, and regular patterning to distribute the post electrodes shall be avoided. The regular patterning (such as an arrangement to align the post electrodes at different circles along the same radial line) would lead to generate plenty void zones, and thus further adjusting the post electrodes is required.

Following table lists empirical or experimental evidences about the aforesaid adjustment of post electrodes, showing distributions of the post electrodes (including quantities and positions) for each circle by having the reference arc length=110 as an example.

| | | | Adj. | | Adj. | | Adj. | | Adj. | | Adj. | | Adj. | | Adj. |
|---|---|---|---|---|---|---|---|---|---|---|---|---|---|---|---|
| Cir. | | 1st | 1st | 2nd | 2nd | 3rd | 3rd | 4th | 4th | 5th | 5th | 6th | 6th | 7th | 7th |
| # | Q'ty | pos. | pos. | pos. | pos. | pos. | pos. | pos. | pos. | pos. | pos. | pos. | pos. | pos. | pos. |
| 1 | 3 | 276 | 276 | 396 | 36 | 516 | 156 | | | | | | | | |
| 2 | 3 | 188 | 188 | 308 | 308 | 428 | 68 | | | | | | | | |
| 3 | 4 | 170 | 170 | 260 | 260 | 350 | 350 | 440 | 80 | | | | | | |
| 4 | 4 | 200 | 200 | 290 | 290 | 380 | 20 | 470 | 110 | | | | | | |
| 5 | 5 | 62 | 62 | 134 | 134 | 206 | 206 | 278 | 278 | 350 | 350 | | | | |
| 6 | 5 | 5 | 5 | 77 | 77 | 149 | 149 | 221 | 221 | 293 | 293 | | | | |
| 7 | 6 | 244 | 244 | 304 | 304 | 364 | 4 | 424 | 64 | 484 | 124 | 544 | 184 | | |
| 8 | 6 | 137 | 137 | 197 | 197 | 257 | 257 | 317 | 317 | 377 | 17 | 437 | 77 | | |
| 9 | 7 | 124 | 124 | 175.4 | 175.4 | 266.8 | 266.8 | 278.2 | 278.2 | 329.6 | 329.6 | 381 | 21 | 432.4 | 72.4 |
| 10 | 7 | 87 | 87 | 138.4 | 138.4 | 189.8 | 189.8 | 241.2 | 241.2 | 292.6 | 292.6 | 344 | 344 | 395.4 | 35.4 |

In addition, positions for post electrodes can be systematically or mathematically determined. In the case that the circles have the same quantity of the post electrodes, angling of the post electrodes at the circle X and the circle X+1 can be obtained according to the following algorithm.
360/2n (n is the quantity of the post electrodes at the circle X or the circle X+1);
   in which a negative sign is chosen if n is an odd integer, and a positive sign is chosen if n is an even integer.
   The distribution of the post electrodes at the instant circle is based on a criterion of evenly distributing the post electrodes within a 360 range. Namely, as the quantity of the post electrodes is 3, then angular spacing of the distribution would be 360/3=120. In the case that both the first circle and the second circle have 3 post electrodes, then angular difference between the post electrodes at the first circle and the second circle would be 360/(2×(−3))=−60. If the post electrodes at the first circle are disposed at 0, 120 and 240, then the distribution of the post electrodes at the second circle would be determined by having the 0-degree post electrode at the first circle as a reference. Based on the uniform angular spacing between the post electrodes (i.e., 360/3=120), the post electrodes at the second circle would be disposed at (0(360)−60)300, (300+120)60 and (60+120)180. (Under the concept of 360 for a circle, the position 320+120=440 exceeds 360 of a circle, and so the 440 position would be amended by 440−360=60.)

If the quantities of the post electrodes at the circles X and X+1 are different, then following algorithm can be used.
(360/n−360/(n+1));
   in which a negative sign is chosen to lead the bracket if n is an odd integer, and a positive sign is chosen to lead the bracket if n is an even integer.

If (360/n−360/(n+1))<10, then the algorithm would be adjusted as follows.
(360/n−360/(n+1))×n/2;
   in which a negative sign is chosen to lead the bracket if n is an odd integer, and a positive sign is chosen to lead the bracket if n is an even integer.

Hence, the four post electrodes at the third circle would be disposed at 60−(360/3−360/4)=30, 120, 210, 300. If the fourth circle has also four post electrodes, then the angular spacing for the first post electrode would be 30+360/(2×4)=75, and the four post electrodes at the fourth circle would be disposed at 75, 145, 235, 325.

According to the aforesaid calculations, the position distribution to all the post electrodes is listed below.

| | | 1 | 2 | 3 | 4 | 5 | 6 | 7 |
|---|---|---|---|---|---|---|---|---|
| 1 | 3 | 0 | 120 | 240 | | | | |
| 2 | 3 | 60, 0 + (360/(2 × (−3)) = −60 (300) | 180 | 60 | | | | |
| 3 | 4 | 60 − (360/3 − 360/4) = 30 | 120 | 210 | 300 | | | |
| 4 | 4 | 30 + (360/(2 × 4)) = 75 | 165 | 255 | 345 | | | |
| 5 | 5 | 75 + (360/4 − 360/5) = 93 | 165 | 237 | 309 | 21 | | |
| 6 | 5 | 21 + (360/(2 × (−5)) = −15(345) | 57 | 129 | 201 | 273 | | |
| 7 | 6 | 57 − (360/5 − 360/6) = 45 | 105 | 165 | 225 | 285 | 345 | |
| 8 | 6 | 45 + (360/(2 × 6)) = 75 | 135 | 195 | 225 | 315 | 15 | |
| 9 | 7 | 15 + [(360/6 − 360/7) × 6/2] = 40.8 | 92.2 | 143.6 | 195 | 246.4 | 297.8 | 349.2 |
| 10 | 7 | 40.8 + (360/(2 × (−7))) = 15.1 | 66.5 | 117.9 | 169.3 | 220.7 | 272.1 | 323.5 |

As described above, firstly, criteria for determining the position distribution of the post electrodes are as follows.
(1) Within the ring area having the post electrodes, the quantity of the post electrodes at the outer circle is no less than (i.e., more than or equal to) that at the inner circle. Namely, the quantities of the post electrodes at these concentric circles are in an ascending series from the inmost circle to the outmost circle.
(2) For two neighboring concentric circles, the diameter difference in between can't exceed twice the diameter of the post electrode, such that the corresponding trace rings can contact each other at least. Preferably, the diameter difference between the two neighboring circles is less than twice the diameter of the post electrode, such that the corresponding trace rings (i.e., the corresponding plasma processing areas) can overlap.

Secondly, the method for determining the quantity of the post electrodes at individual circle is as follows.

Least circumferential rounding percentage: after selecting a reference arc length, calculate the least difference in every circumference;
(1) Circumferential Rounding Percentage=(Average circumferential arc length shared by each single post electrode at the circle−Reference arc length)/Reference arc length×100%
(2) Considering a second solution to dispose the post electrodes: With an extended processing area, the total quantity of the post electrodes may be big (i.e., the estimated quantity of the post electrodes at the outer circle is big as well). Then, a second solution may be proposed to relax the acceptable circumferential rounding percentage; for example, to about 10%. Thus, the total quantity of the post electrodes can be reduced to a number less than that simply determined by the aforesaid criterion upon determining the minimum maximal circumferential rounding percentage.

Thirdly, criteria for determining the position distribution of the post electrodes are as follows.
(1) Basically, the post electrodes at the same circle are evenly distributed; i.e., spaced by 360/n, where n is the quantity of the post electrodes at the instant circle.
(2) The post electrodes at neighboring circles should be prevented from aligning along the same radial extension line, and partly overlapping of the neighboring trace rings is expected (i.e., radial spacing between neighboring circles is less than twice diameter of the post electrode).
(3) Distribution of the post electrodes can be determined by referring to a reference point at a specific circle. By adding a constant angular shift from a random number, the angling of the first position for locating the post electrode is determined, and then the rest of the positions can be determined by performing a relevant algorithm (not unique).
(4) If the random number is used to determine the first position for disposing the post electrode, and if the radial spacing between two neighbouring circles is less than the diameter of the post electrode, then re-picking another random number so as to avoid overlapping of post electrodes is necessary.
(5) In order to make the position distribution of the post electrodes uniform over the entire annular electrode distribution area, an angular patterning in locating the post electrodes shall be avoided.

Finally, the method to avoid overlapping between the post electrodes at neighboring circles is as follows.
(1) Perform angular shifting simultaneously to all the post electrodes at the inner or outer circle.
(2) Move one of the overlapped or interfered post electrodes to a safe position where direct contact between two neighboring post electrodes can be avoided, and also make sure to maintain a free-of-contact state between any of the post electrodes.

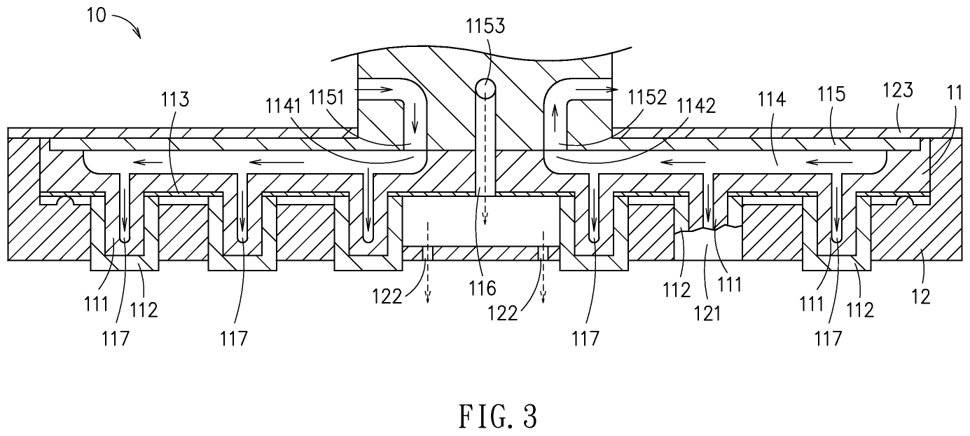

Referring now to FIG. 1 and FIG. 3, the upper electrode assembly 10 includes a main body 11 made of (or at least including) a conductive material and a base block 12 made of (or at least including) a dielectric material. On one side of the main body 11 (i.e., the bottom surface of the main body 11 in the figure), a plurality of post electrodes 111 are furnished in a protrusive manner Each of the post electrodes 111 is connected with a plasma power source (not shown in the figure), and each of the post electrodes 111 can be formed as a cylindrical pillar with an axial end extending toward the lower electrode assembly 20. As shown in FIG. 3, the post electrodes 111 and the main body 11 can be integrated as a unique piece. Alternatively, fasteners or connectors can be applied to engage the post electrodes 111 onto the main body 11. For example, an extension portion to plug the main body 11 can be provided to a bottom end of the post electrode 111, so that a C ring can be applied to hold fixedly the protrusion inside the main body 11. Each of the post electrodes 111 can be furnished with a post-electrode sock 112 made of a dielectric material. The base block 12 has a plurality of first holes 121 located in correspondence with the plurality of post electrodes 111. While the main body 11 is set inside the base block 12, the plurality of post electrodes 111 sleeved individually by the corresponding post-electrode socks 112 penetrate through the corresponding first holes 121 and then expose partly over the base block 12. Within the plasma deficiency area 13 at the upper electrode assembly 10, a plurality of vent holes 122 are provided. A spacer plate 113 made of a dielectric material is disposed on the surface of the main body 11 that protrudes the plurality of post electrodes 111. The space plate 123 can be a ceramic plate, a Teflon sheet, or any the like. On a surface of the main body 11 opposing the surface having the plurality of post electrodes 111 (i.e., the top surface of the main body 11 in the figure), a first cooling channel 114 and a first gas inlet 116 are constructed. An axial center of each the post electrode 111 is furnished with a second cooling channel 117 communicated spatially with the first cooling channel 114 so as to form a cooling route.

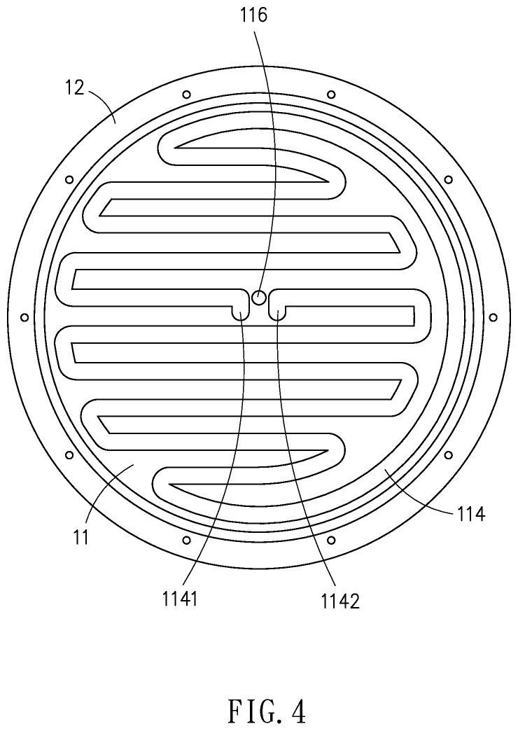

Referring now to FIG. 3 and FIG. 4, the first cooling channel 114 as a continuous fluid path has a fluid-in port 1141 and a fluid-out port 1142. On the side of the main body 11 opposing the side thereof having the plurality of post electrodes 111, a first cover plate 115 made of a conductive material is introduced to cover the first cooling channel 114. The first cover plate 115 has a fluid inlet 1151, a fluid outlet 1152 and a second gas inlet 1153. The second gas inlet 1153 is connected spatially to the vent holes 122 via the first gas inlet 116. A cooling fluid enters the fluid-in port 1141 via the fluid inlet 1151, and leaves the first cooling channel 114 via the fluid-out port 1142 and the fluid outlet 1152. In addition, a second cover plate 123 made of a dielectric material is furnished to the base block 12 at the side away from the plurality of post electrodes 111 so as for further covering the first cover plate 115. When the second cover plate 123 is sealed in position, a close fluid loop can be formed by integrating the first cooling channel 114 and the second cooling channel 117, via which the cooling fluid can be introduced to cool down the upper electrode assembly 10, such that the temperature of the upper electrode assembly 10 can be maintained.

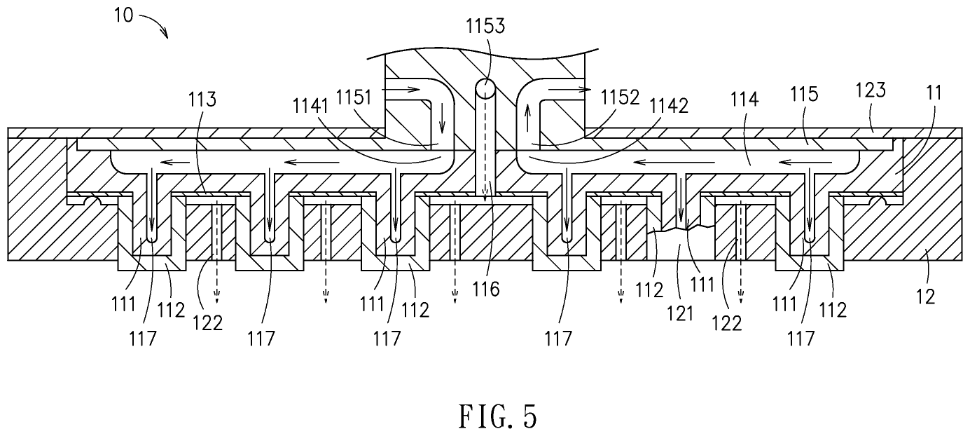

Referring now to FIG. 5, in this embodiment, the vent holes 122 are provided to the plurality of post electrodes 111 for performing air introduction. It is noted that, in the different embodiment shown in FIG. 3, the vent holes 122 are constructed within the plasma deficiency area 13.

Referring to FIG. 1 and FIG. 5, the upper electrode assembly 10 includes a main body 11 made of (or at least including) a conductive material and a base block 12 made of (or at least including) a dielectric material. On one side of the main body 11 (i.e., the bottom surface of the main body 11 in the figure), a plurality of post electrodes 111 are furnished in a protrusive manner Each of the post electrodes 111 is connected with a plasma power source (not shown in the figure), and each of the post electrodes 111 can be formed as a cylindrical pillar with an axial end extending toward the lower electrode assembly 20. As shown in FIG. 5, the post electrodes 111 and the main body 11 are integrated as a unique piece. Alternatively, fasteners or connectors can be applied to engage the post electrodes 111 and the main body 11. For example, a bottom protrusion for being planted into the main body 11 can be provided to the post electrode 111, so that a C ring can be applied to hold fixedly the protrusion inside the main body 11. Each of the post electrodes 111 can be sleeved with a post-electrode sock 112 made of a dielectric material. The base block 12 has a plurality of first holes 121 located in correspondence with the plurality of post electrodes 111. While the main body 11 is set inside the base block 12, the plurality of post electrodes 111 sleeved individually by the corresponding post-electrode socks 112 penetrate through the corresponding first holes 121 and then expose partly over the base block 12. A plurality of vent holes 122 are provided individually to the places separating the two neighboring post electrodes 111. A spacer plate 113 made of a dielectric material is disposed on the surface of the main body 11 that protrudes the plurality of post electrodes 111. The spacer plate 123 can be a ceramic plate, a Teflon sheet, or any the like. On a surface of the main body 11 opposing the surface having the plurality of post electrodes 111 (i.e., the top surface of the main body 11 in the figure), a first cooling channel 114 and a first gas inlet 116 are constructed. An axial center of each the post electrode 111 is furnished with a second cooling channel 117 communicated spatially with the first cooling channel 114 so as to form a cooling route.

Referring now to FIG. 4 and FIG. 5, the first cooling channel 114 as a continuous fluid path has a fluid-in port 1141 and a fluid-out port 1142. On the side of the main body 11 opposing the side thereof having the plurality of post electrodes 111, a first cover plate 115 made of a conductive material is introduced to cover the first cooling channel 114. The first cover plate 115 has a fluid inlet 1151, a fluid outlet 1152 and a second gas inlet 1153. The second gas inlet 1153 is connected spatially to the vent holes 122 via the first gas inlet 116. A cooling fluid enters the fluid-in port 1141 via the fluid inlet 1151, and leaves the first cooling channel 114 via the fluid-out port 1142 and the fluid outlet 1152. A foreign process gas flows through the second gas inlet 1153 and the first gas inlet 116, then leaves the base block 12 via the plurality of vent holes 122, and reaches the post-electrode reaction area between the upper electrode assembly 10 and the lower electrode assembly 20. In addition, a second cover plate 123 made of a dielectric material is furnished to the base block 12 at the side away from the plurality of post electrodes 111 so as for further covering the first cover plate 115. When the second cover plate 123 is sealed in position, a close fluid loop can be formed by integrating the first cooling channel 114 and the second cooling channel 117, via which the cooling fluid can be introduced to cool down the upper electrode assembly 10, such that the temperature of the upper electrode assembly 10 can be maintained.

It shall be explained that, in the aforesaid embodiments, the purpose of the base block 12, the post-electrode sock 112, the spacer plate 113 and the second cover plate 123, all made of the dielectric material, is to stimulate all the post electrodes 111 for generating the plasma uniformly, and also to prevent electric particles of the plasma from directly bombarding the conductive electrodes, upon which arc discharge would damage the electrodes. Alternatively, to serve the same purpose, the base block 12 and the post-electrode socks 112 can be integrated as a whole to cover the upper electrode assembly 10 and the dielectric post electrodes 111. In addition, it shall be understood that FIG. 1 through FIG. 5 are prepared simply for demonstrating structuring of the upper electrode assembly, and not configured in exact proportionality.

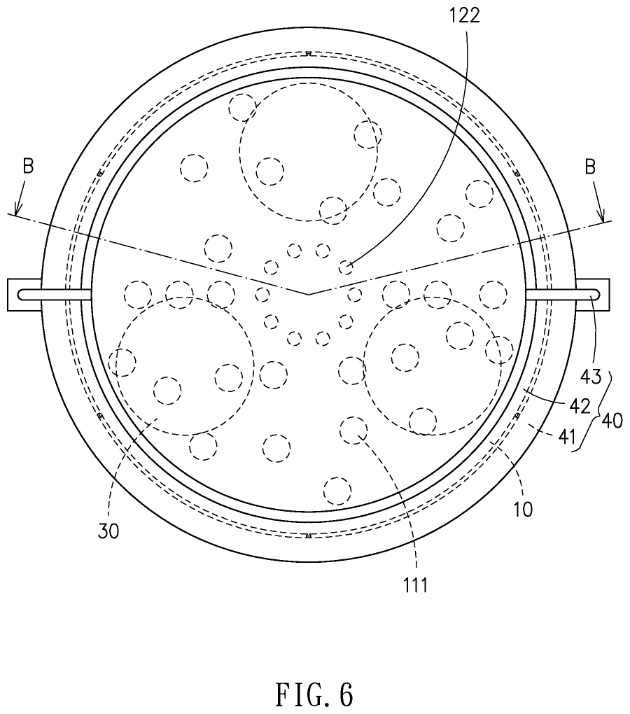

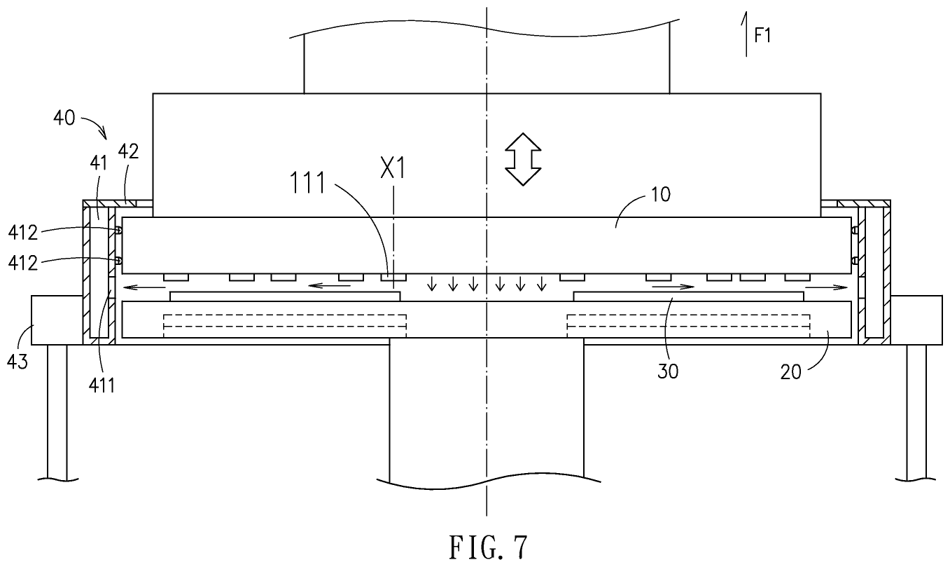

Referring now to FIG. 6 and FIG. 7, a reaction shield 40, provided between the upper electrode assembly 10 and the lower electrode assembly 20, includes a chamber 41, a supportive frame 42 and a drive device 43. The annular chamber 41 has an inner diameter larger than outer diameters of the upper electrode assembly 10 and the lower electrode assembly 20. The chamber 41 is furnished with at least one communicative hole 411 and valves (not shown in the figure) for controlling in/out of the process gas. The chamber 41 can be made of a metal, a dielectric material, or any appropriate material. The supportive frame 42, mounted top to the chamber 41, is hollow and annular, and performs as an upper stop structure. The supportive frame 42 can be made of a metal, a dielectric material, or any appropriate material. The drive device 43, connected to the chamber 41, is to drive simultaneously the chamber 41 and the supportive frame 42.

Referring now to FIG. 3 and FIG. 7, the second gas inlet 1153, the first gas inlet 116, the vent holes 122 of the upper electrode assembly 10, the post plasma-generating area between the upper electrode assembly 10 and the lower electrode assembly 20, the communicative holes 411 of the chamber 41, and the inner space of the chamber 41 are all communicated spatially to form a continuous path for the process gas. Accordingly, when the second gas inlet 1153 is connected to a mixture tank of the process gas, and when the chamber 41 is connected spatially with an exhaust-gas treatment system, the process gas can be led to the second gas inlet 1153, and then the process gas flows though the first gas inlet 116, the vent holes 122 of the upper electrode assembly 10, the plasma-reaction zone between the upper electrode assembly 10 and the lower electrode assembly 20, the communicative holes 411 of the chamber 41, and the inner space of the chamber 41, and finally is exhausted to the exhaust-gas treatment system. In this application, the vent holes 122 serve as gas-feeding holes, while the communicative holes 411 server as vacuum holes. The flow direction of the process gas is shown by arrows in FIG. 3 and FIG. 7.

Contrarily, if the chamber 41 is connected to a mixture tank of the process gas, and the second gas inlet 1153 is connected to an exhaust-gas treatment system, then the process gas can be led into the chamber 41, and the process gas further flows through the communicative holes 411 of the chamber 41, the plasma-reaction zone between the upper electrode assembly 10 and the lower electrode assembly 20, the vent holes 122 of the upper electrode assembly 10, the first gas inlet 116 and the second gas inlet 1153, and finally reaches the exhaust-gas treatment system. With the valves of the chamber 41, in/out of the process gas with respect to the chamber 41 can be controlled. In this application, the communicative holes 411 server as gas-feeding holes, while the vent holes 122 serve as vacuum holes. The flow direction of the process gas is established by the reverse directions of the arrows in FIG. 3 and FIG. 7.

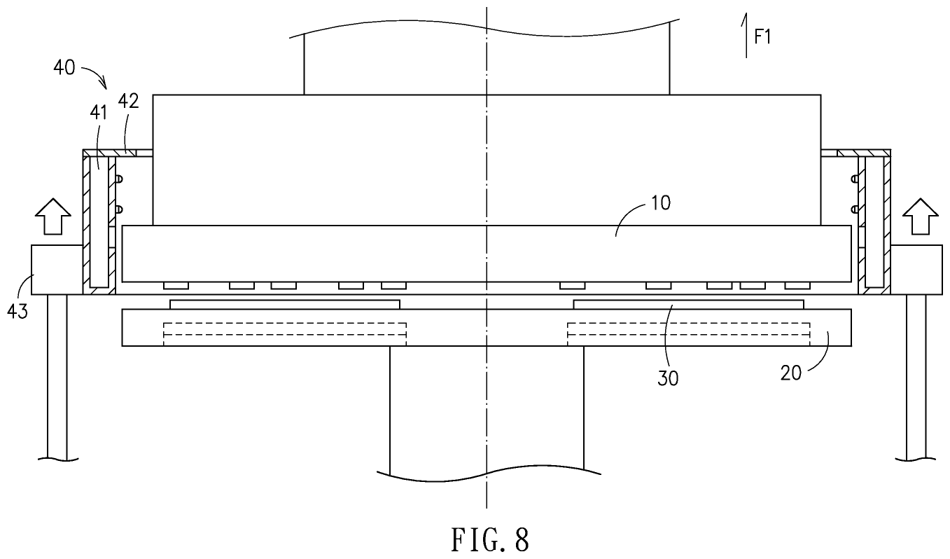

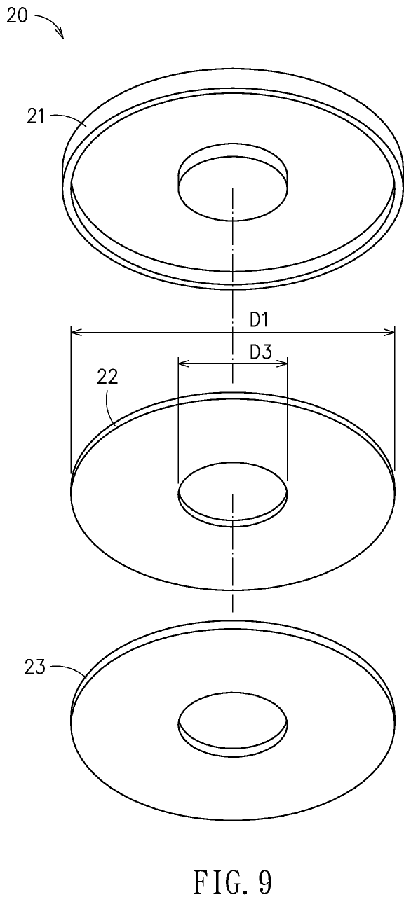

Referring now to FIG. 7 and FIG. 8, the drive device 43 can control the chamber 41 to reciprocally move in a direction parallel to the first direction F1 between a process position (FIG. 7) and a material-loading/unloading position (FIG. 8). A plurality of rollers 412 for smoothly moving the reaction shield 40 up and down are furnished to the inner wall of the chamber 41 and to contact the outer wall of the upper electrode assembly 10. The first direction F1 is parallel to the axial direction X1 of the post electrodes 111, but perpendicular to the water level. As shown in FIG. 7, when the chamber 41 moves to the process position, a lower edge of the chamber 41 is flush with or lower than a bottom surface of the lower electrode assembly 20. As shown in FIG. 8, when the drive device 43 lifts the chamber 41 up to the material-loading/unloading position, the lower edge of the chamber 41 is higher than a top surface of the lower electrode assembly 20, such that the lower electrode assembly 20 can be moved away from the plasma-generating region to replace the workpieces 30 for plasma processing. After the reloading, the drive device 43 lowers the chamber 41 to the process position shown in FIG. 9, for another plasma processing upon the new-loaded workpieces 30.

In this disclosure, functions of the reaction shield 40 are listed as follows:

(1) To shield the space between the lower and upper electrode assemblies, such that the gas composition within this space can be controllable, and avoid influence of foreign air;

(2) To provide sufficient communicative holes for introducing, flowing and exhausting the process gas, so that the process gas after the plasma process can be quickly replaced;

(3) To provide a guide device to isolate the material loading and unloading; and

(4) To provide holes (or the communicative holes) for guiding the flow of process gas and/or altering the style of introducing the process gas, such that the vent holes 122 can be neglected.

Referring now to FIG. 9, the lower electrode assembly 20 includes a carrier 21, a lower cover plate 23 and a built-in type electrode 22. The built-in type electrode 22 is an annular part. The carrier 21 and the lower cover plate 23, both made of dielectric materials, are to sandwich and also wrap the built-in type electrode 22.

Referring now to FIG. 2 and FIG. 9, a concentric circular area surrounded by the ring area formed by revolving the built-in type electrode 22 is defined to be the plasma deficiency area 13. An outer diameter D1 of the ring area defined with the built-in type electrode 22 is equal to or larger than the diameter D2 of FIG. 2 related to the trace rings generated by the post electrodes 111. An inner diameter D3 of the ring area defined with the built-in type electrode 22 is equal to or smaller than the diameter D4 of FIG. 2 related to the trace rings generated by the post electrodes 111. It shall be explained that the reason to design an annular built-in type electrode 22 is to remove construction of part of the lower electrode assembly 20 at the place in correspondence with the plasma deficiency area 13 of the upper electrode assembly 10, such that production cost can be substantially lowered. In other words, if the cost is not the concerned, the built-in type electrode 22 can also be built as a broad solid disk to fill the empty circular area defined with the diameter D3.

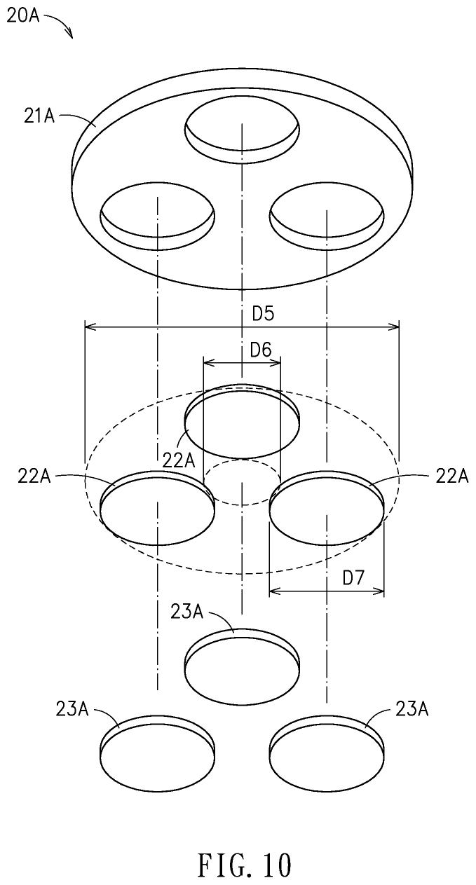

Referring now to FIG. 10, the lower electrode assembly 20A includes a carrier 21A, three lower cover plates 23A and three built-in type electrodes 22A. Each of the three built-in type electrodes 22A is formed as a solid disk. The carrier 21A and the lower cover plates 23A are all made of dielectric materials to sandwich and wrap the three built-in type electrodes 22A. Definitely, according to this disclosure, the quantity of the built-in type electrodes 22A is not limited to the number three.

Referring now to FIG. 2 and FIG. 10, a plasma deficiency area 13 is defined to the central area surrounded by the trace rings formed by revolving the built-in type electrodes 22A about a center line of the device. An outer diameter D5 of the trace rings defined with the built-in type electrodes 22A is equal to or larger than the diameter D2 of FIG. 2 related to the trace rings generated by the post electrodes 111. An inner diameter D6 of the trace rings defined with the built-in type electrodes 22A is equal to or smaller than the diameter D4 of FIG. 2 related to the trace rings generated by the post electrodes 111. A diameter D7 of the built-in type electrode 22A is equal to or larger than a diameter D8 of the corresponding workpiece 30.

In this embodiment, the built-in type electrode 22A is built as a solid disk, and the place to locate the workpiece for plasma processing is right under the built-in type electrode 22A, as shown in FIG. 10. In comparison with the embodiment shown in FIG. 9, this embodiment can further reduce the production cost of the lower electrode assemblies. In addition, the quantity of the built-in type electrodes 22A can be decided per practical requirements. For example, the quantity of the built-in type electrodes 22A can be three as the embodiment in FIG. 10, or can be one or two. In the case of three built-in type electrodes 22A, the quantity of the workpieces to be plasma processed at a unit process can be one, two or three. In the case of two built-in type electrodes 22A, the quantity of the workpieces to be plasma processed at a unit process can be one or two. In this type of embodiments, the workpiece to be processed needs to be placed right under the built-in type electrode where the plasma is generated, and thus power consumption can be substantially reduced.

In FIG. 9 and FIG. 10, the built-in type electrode can be formed as a ring or a solid disk to convenience the generation as well the control of plasma by the post electrodes.

According to the aforesaid design criteria, the principles to setup the plasma deficiency area 13 include the steps of:

(1) confirming a size (diameter) of the lower electrode assembly 20, 355 mm for example;

(2) confirming a size (diameter) of the workpiece 30 to be processed, 4in (wafer) for example;

(3) determining the distribution of the outer post electrodes 111, equal to or larger slightly than the outer rim of the built-in type electrode 22, 22A; and

(4) determining the distribution of the inner post electrodes 111, equal to or smaller slightly than the lower electrode assembly 20.

In summary, the plasma processing device provided by this disclosure is a wide-area atmospheric-pressure plasma processing device applicable to the hard and brittle materials (such as silicon carbide), and able to uplift the polishing efficiency. By applying the plasma to dissociate the gas so as further to induce physical and/or chemical reactions for generating reaction materials to react with the hard/brittle materials surfacing the workpiece, a surface modification upon the workpiece or removal of a surface layer of the workpiece can be obtained. Thereupon, the conventional shortcomings (both in efficiency and in cost) of the chemical mechanical polishing on the hard/brittle materials can be resolved. In this disclosure, at least following features are included: (1) an upper electrode assembly having a plurality of protrusions (i.e., the post electrodes) arranged in a discrete and asymmetric manner; (2) an annular plasma-generating region defined by the plurality of post electrodes; and, (3) a lower electrode assembly having built-in type electrodes arranged to pair the annular plasma-generating region defined by the upper electrode assembly. When a high-frequency plasma power source (RF for example) energizes the upper electrode assembly, plasma would be generated between the protrusions (i.e., the post electrodes) of the upper electrode assembly and the corresponding built-in type electrodes of the lower electrode assembly. The lower electrode assembly is rotated by a drive device whose rotation speed can be adjusted. When the lower electrode assembly is rotated, the annular distribution arrangement of the post electrodes at the upper electrode assembly would form a better plasma coverage over the lower electrode assembly as well as the workpieces thereon. Thereupon, quality plasma processing over an entire processing surface locating plural workpieces (SiC wafers for example) can be simultaneously provided by the plasma processing device in this disclosure. Also, since an atmospheric-pressure plasma system can be incorporated, thus the plasma processing device of this disclosure can be structured to provide a broader plasma processing area, without including a vacuum chamber. In this disclosure, the movable reaction shield between the upper and lower electrode assemblies is provided to protect the plasma-generating region, such that possible foreign environmental disturbances can be substantially reduced, and also the process gas can be rapidly and completely exhausted and/or replaced if necessary.

In addition, since the plasma processing device provided by this disclosure is a dry-type device operated in the atmospheric environment, thus it can be incorporated easily with a conventional chemical mechanical polishing apparatus. Experimental results have proven that the polishing removal rate upon the existing 4-in hard brittle silicon carbide wafer products has been increased by 657%, from 0.23 um/hr by using the conventional polishing apparatus to 1.51 um/hr by using the plasma processing device provided by this disclosure.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A plasma processing device, comprising:
an upper electrode assembly, including a plurality of post electrodes protruding toward a lower electrode assembly from a reaction surface of the upper electrode assembly, the plurality of post electrodes being connected with a plasma power source, a plasma deficiency area being defined in a central area of the upper electrode assembly where none of the plurality of post electrodes is located, an annular electrode distribution area being defined between a boundary of the plasma deficiency area and a smallest circumference encircling all the plurality of post electrodes, an upper plasma-generating region being formed under the plurality of post electrodes with respect to the annular electrode distribution area; and
the lower electrode assembly, located under and separated from the upper electrode assembly, having at least one built-in type electrode coated by a dielectric material, being grounded and rotatable;
wherein a plasma-reaction zone including the plasma-generating region is formed between the upper electrode assembly and the lower electrode assembly.

2. The plasma processing device of claim 1, wherein the at least one built-in type electrode is at least circularly arranged, an lower annular plasma-generating area is defined by revolving the at least one built-in type electrode, a concentric circular empty area defined inside the lower annular plasma-generating area is located in correspondence with the plasma deficiency area, and an outer diameter of the lower annular plasma-generating area is no less than another outer diameter of the annular electrode distribution area.

3. The plasma processing device of claim 2, wherein the at least one built-in type electrode is annular shaped, and an inner diameter of the lower annular plasma-generating area is no more than another inner diameter of the annular electrode distribution area.

4. The plasma processing device of claim 2, wherein the at least one built-in type electrode is consisted of a plurality of solid disks circularly arranged.

5. The plasma processing device of claim 2, wherein a diameter of the at least one built-in type electrode is no less than that of a workpiece to be processed by the corresponding built-in type electrode.

6. The plasma processing device of claim 1, wherein the upper electrode assembly includes a main body made of a conductive material, the plurality of post electrodes are located at one side of the main body, the main body is furnished with a first cooling channel, and an axial center of each of the plurality of post electrodes is furnished with a second cooling channel communicated spatially with the first cooling channel to form a cooling route.

7. The plasma processing device of claim 1, wherein the plasma deficiency area is distributed with a plurality of vent holes.

8. The plasma processing device of claim 1, further including a reaction shield located between the upper electrode assembly and the lower electrode assembly, wherein the reaction shield includes:
a chamber, annular shaped to have an inner diameter larger than any of outer diameters of the upper electrode assembly and the lower electrode assembly, having at least one communicative hole;
a supportive frame, being hollow and annular, connected with the chamber; and
a drive device for moving the chamber and the supportive frame simultaneously.

9. The plasma processing device of claim 8, wherein a continuous path for flowing a process gas is formed by integrating spatially the plurality of vent holes of upper electrode assembly, the plasma-reaction zone between the upper electrode assembly and the lower electrode assembly, the at least one communicative hole, and an interior of the chamber.

10. The plasma processing device of claim 9, wherein one of the plurality of vent holes and the interior of the chamber is connected to a mixture tank of the process gas, while another thereof is connected to an exhaust-gas treatment system.

11. The plasma processing device of claim 8, wherein the chamber is furnished with a valve to control in/out of the process gas with respect to the chamber.

12. The plasma processing device of claim 8, wherein the drive device controls the chamber to reciprocally move in a direction parallel to a first direction between a process position and a material-loading/unloading position, and the first direction is parallel to an axial direction of one of the plurality of post electrodes but perpendicular to the water level; wherein, when the chamber moves to the process position, a lower edge of the chamber is flush with or lower than a lower surface of the lower electrode assembly; wherein, when the drive device lifts the chamber up to the material-loading/unloading position, the lower edge of the chamber is higher than a top surface of the lower electrode assembly.

13. The plasma processing device of claim 8, wherein the chamber and the supportive frame are made of one of a metal and a dielectric material.

14. The plasma processing device of claim 1, wherein any of the plurality of post electrodes is a conductive material coated by a dielectric material, and the plurality of post electrodes are arranged to surround a center so as to form a plurality of concentric circles, each of the plurality of concentric circles having at least one of the plurality of post electrodes.

15. The plasma processing device of claim 14, including two neighboring concentric circles out of the plurality of concentric circles having the same quantity of the post electrodes.

16. The plasma processing device of claim 14, wherein, in any two neighboring concentric circles of the plurality of concentric circles, a quantity of the post electrodes in an outer circle of the two neighboring concentric circles is bigger than another quantity of the post electrodes in an inner circle thereof.

17. The plasma processing device of claim 14, wherein each of the plurality of concentric circles is accompanied by a trace ring generated by revolving the post electrodes in the same circle about the center, two said neighboring trace rings with respect to two said neighboring concentric circles are at least contacted to each other, and the annular electrode distribution area is formed by integrating all said trace rings of the plurality of concentric circles.
